(19) United States
(12) Patent Application Publication
(10) Pub. No.: US 2015/0340274 A1
(43) Pub. Date: Nov. 26, 2015

(54) METHODS FOR PRODUCING INTEGRATED CIRCUITS WITH AN INSULTATING LAYER

(71) Applicant: GLOBALFOUNDRIES, Inc., Grand Cayman (KY)

(72) Inventors: Errol Todd Ryan, Clifton Park, NY (US); Sukwon Hong, Watervliet, NY (US)

(73) Assignee: GLOBALFOUNDRIES, Inc., Grand Cayman (KY)

(21) Appl. No.: 14/286,029

(22) Filed: May 23, 2014

(51) Int. Cl. H01L 21/762; H01L 21/324; H01L 21/02

(52) U.S. Cl. CPC H01L 21/76224; H01L 21/02271; H01L 21/324

(57) ABSTRACT

Methods for producing integrated circuits are provided. A method for producing an integrated circuit includes forming an insulating layer overlying a substrate, where the insulating layer is formed within a trench. The insulating layer is infused with water, and the insulating layer is annealed while being irradiated. The insulating layer is annealed at a dry anneal temperature of about 800 degrees centigrade or less.

### TECHNICAL FIELD

The technical field generally relates to methods for producing integrated circuits, and more particularly relates to method of producing integrated circuits with an insulating layer while adhering to a thermal budget for the integrated circuit.

### BACKGROUND

Silicon dioxide is used as an insulator in many integrated circuits, and the quality of the silicon dioxide increases as the density increases. High quality silicon dioxide is more resistant to certain etchants, and may be etched at a more consistent rate than low quality silicon dioxide, so high quality silicon dioxide can simplify downstream processing operations. Some existing processes deposit an insulating layer within trenches, and the aspect ratio of the trenches tends to increase as the size of the integrated circuit decreases. Many insulating layer deposition processes are designed to fill high aspect ratio trenches, but such insulating layer deposition processes may not produce dense, high quality silicon dioxide insulation. For example, some flowable chemical vapor deposition (FCVD) processes are capable of filling trenches with high aspect ratios, but the insulating material is a silicon and nitrogen containing film. Some high aspect ratio processes (HARP) are capable of depositing silicon oxide within trenches having high aspect ratios, but the silicon oxide is generally not a high quality, dense material.

Historically, the FCVD or HARP materials have been exposed to a steam anneal at a temperature of about 500 degrees centigrade (° C.) to convert silicon/nitrogen bonds to silicon oxide bonds, and to begin the densification process. The steam anneal is followed by a dry anneal at an anneal temperature of about 1,000° C. or more, and the high anneal temperature can produce dense, high quality silicon dioxide. However, some substrates have a thermal budget, and the substrate can be degraded by annealing processes that exceed the thermal budget temperature. For example, many substrates that include germanium have a thermal budget of less than 1,000° C., where the thermal budget tends to decrease as the percentage of germanium in the substrate increases. Some III-V substrates, such as gallium arsenide or indium gallium arsenide, have a thermal budget of about 600° C., or about 400° C., and other thermal budget temperature limits exist for other substrates or components in an integrated circuit.

As the size of integrated circuits decreases, the size of components in the integrated circuit also decreases. Fins are formed in the substrate of many integrated circuits, and the strength of the fins decreases as the size of the fin decreases. When the fin becomes small, the densification process tends to bend or break the fins from the substrate, especially when the integrated circuit is annealed at high temperatures. Silicon dioxide has a different coefficient of thermal expansion than the material of some fins, so the higher the temperature of the anneal, the more stress is transferred to the fins when the anneal is performed.

Accordingly, it is desirable to provide methods of producing integrated circuits with an insulating material that is capable of filling high aspect trenches, where the insulating material can be densified at low temperatures. In addition, it is desirable to provide methods of forming integrated circuits with narrow fins, where the fins are not bent or damages when insulating material between adjacent fins is densified. Furthermore, other desirable features and characteristics of the present embodiment will become apparent from the subsequent detailed description and the appended claims, taken in conjunction with the accompanying drawings and this background of the invention.

### BRIEF SUMMARY

Integrated circuits and methods for producing the same are provided. In an exemplary embodiment, a method for producing an integrated circuit includes forming an insulating layer overlying a substrate, where the insulating layer is formed within a trench. The insulating layer is infused with water, and the insulating layer is annealed while being irradiated. The insulating layer is annealed at a dry anneal temperature of about 800 degrees centigrade or less.

A method for producing an integrated circuit is provided in another embodiment. An insulating layer is formed overlying a substrate and within a trench, where the insulating layer includes a silicon and nitrogen containing film. The silicon and nitrogen containing film is converted to silicon dioxide, and densified with a dry anneal while being irradiated. Densifying the insulating layer increases a density of the insulating layer by about 0.05 grams per cubic centimeter or more.

A method of producing an integrated circuit is provided in yet another embodiment. A plurality of fins are formed in a substrate, where a trench is defined between adjacent fins. The fins have a fin width of about 10 nanometers or less, and the fins are within about 1 degree of vertical. The trench has an aspect ratio of about a height of 10 or more to a width of 1. An insulating layer is formed within the trench, where the insulating layer fills about 95 volume percent or more of the trench. The insulating layer is densified such that the fins are within about 2 degrees of vertical.

### BRIEF DESCRIPTION OF THE DRAWINGS

The present embodiments will hereinafter be described in conjunction with the following drawing figures, wherein like numerals denote like elements, and wherein:

FIGS. 1-5 illustrate, in cross sectional views, a portion of an integrated circuit and methods for its fabrication in accordance with exemplary embodiments.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

An insulating layer is formed overlying a substrate, and the insulating layer is a “gap fill” layer that fills a trench. Flowable type insulating layers are typically used for gap fill applications, so essentially the entire gap is filled with the insulating layer. Many flowable type insulating layers are good at filling gaps, even those with a high aspect ratio, but the high temperature anneals required to convert the insulating material to high quality, dense silicon dioxide may exceed the thermal budget for the substrate, and thermal expansion issues may damage delicate structures on the substrate, as mentioned above. An FCVD insulating layer is good at filling high aspect ratio gaps, but forms a silicon and nitrogen containing film. The silicon and nitrogen containing film can be converted to silicon oxide by infusing the silicon and nitrogen containing film with water and/or annealing it in the presence of steam. The silicon oxide formed may not be as dense as desired, and it can be densified with another anneal. The densification anneal is a dry anneal that removes water and further crosslinks the film, and the temperature of the densification anneal can be reduced by irradiating the insulating layer during the anneal to provide extra energy for the densification. After the insulating layer is densified, additional manufacturing steps may be used to produce the integrated circuit.

Reference is made to FIG. 1. An integrated circuit 10 includes a substrate 12. As used herein, the term “substrate” 12 will be used to encompass substrates 12 formed from semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. Semiconductor material also includes other materials such as relatively pure and impurity-doped germanium, zinc oxide, glass, and the like. Other semiconductor materials include III-V semiconductor materials, such as gallium arsenide, boron nitride, boron phosphide, aluminum antimonide, indium gallium arsenide, and various combinations of compounds in periodic table Groups III and V. In an exemplary embodiment, the semiconductor material is a monocrystalline substrate including silicon and germanium. The substrate 12 may be a bulk wafer (as illustrated) or may be a thin layer of semiconductor material on an insulating layer that, in turn, is supported by a carrier wafer.

Germanium has a melting point of about 937° C., and the thermal budget of silicon germanium substrates 12 is often less than about 1,000° C. The thermal budget may be designed to prevent germanium from melting within the substrate matrix. The “thermal budget” is a limitation on the temperature, or on the exposure time at certain temperatures, that a substrate 12, integrated circuit 10, or other structure can be exposed to without causing unacceptable harm or damage. In some instances, it is desirable to stay as far below the maximum temperature allowed by the thermal budget as possible, because damage may begin at lower temperatures and increase with the temperature. The thermal budget may be set at a point where the damage is considered too severe, but keeping processing temperatures below the thermal budget may reduce damage that is undesirable but may still produce a workable product. The thermal budget for silicon germanium substrates 12 may depend on the concentration of germanium in the substrate 12. Some exemplary thermal budgets include maximum temperatures not to exceed about 1,000° C., or not to exceed about 800° C., or not exceed about 600° C. Some III-V semiconductor materials may have a thermal budget not to exceed about 600° C., or not to exceed about 500° C., or not to exceed about 400° C. in various embodiments. For example, arsenic in some III-V semiconductors may outgas when the thermal budget is exceeded, so the composition of the substrate 12 can change.

In an exemplary embodiment, a plurality of fins 14 are formed in the substrate 12, where the fins 14 are formed by methods and techniques well known to those skilled in the art. A trench 16 is defined between adjacent fins 14, where the trench 16 has a trench height indicated by the double headed arrow labeled 18 and a trench width indicated by the double headed arrow labeled 20. The trench 16 has an aspect ratio that is the trench height 18 relative to the trench width 20, and the aspect ratio may be about 5 or more to 1 in some embodiments, about 10 or more to 1 in other embodiments, and about 20 to 1 in yet other embodiments. In general, the higher the trench aspect ratio, the more difficult it is to fill the trench 16. The fins 14 have a fin width indicated by the double headed arrow labeled 22, and the fin width 22 may be about 10 nanometers or less in some embodiments, or about 20 nanometers or less in other embodiments, or about 30 nanometers or less in yet other embodiments. The smaller the fin width 22, the easier it is to damage the fin 14 because thin fins 14 are more delicate than thicker fins 14 of the same material. The fins 14 may also be essentially vertical, such as within about 1 degree of vertical. Vertical fins 14 are incorporated into many integrated circuits 10.

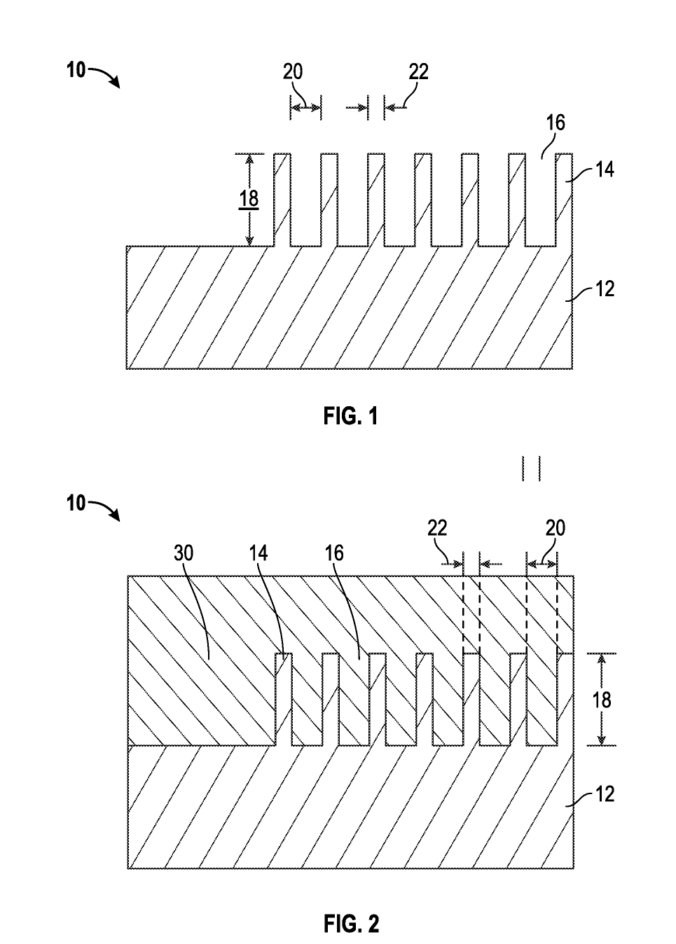

In an exemplary embodiment illustrated in FIGS. 2 and 3, where FIG. 3 is a magnified portion of FIG. 2, an insulating layer 30 is formed overlying the substrate 12 and within the trench 16. The insulating layer 30 may essentially fill the trench 16, such that the insulating layer 30 fills about 95 volume percent or more of the trench 16, and the insulating layer 30 may also extend over and above the trench 16. The insulating layer 30 may be about 200 to about 1,000 nanometers thick in some embodiments, but other thicknesses are also possible. In some embodiments, the trench 16 is formed from the substrate 12, as illustrated, but in other embodiments the trench may be formed from materials other than the substrate 12 (not illustrated), such as a trench formed during manufacture of a replacement metal gate.

The insulating layer 30 may be formed by depositing a silicon and nitrogen containing film using a flowable chemical vapor deposition (FCVD) process. Not to be bound by theory, but the FCVD process may form an oligomer in the gas phase, where the oligomer is flowable such that is flows into the trench 16, and the oligomer may then further polymerize after flowing into position. In an exemplary embodiment, the FCVD is a plasma chemical vapor deposition process that can use a low carbon or carbon-free silicon containing precursor that includes silicon along with a nitrogen containing precursor. The silicon precursor may be trisilylamine amine, disilylamine, monosilylamine, silane, or other precursors, and the nitrogen containing precursor may be ammonia, nitrogen gas, or other compounds. Other FCVD processes may also be used in alternate embodiments. In alternate embodiments, a high aspect ratio process (HARP) may be used to form the insulating layer 30 overlying the substrate 12 and within the trench 16. In an exemplary embodiment, the HARP may form a silicon dioxide insulating layer 30 using ozone and tetraethyl orthosilicate (TEOS) as precursors in a chemical vapor deposition at less than atmospheric pressure, but other precursors or processes may be used in alternate embodiments. Other methods of producing the insulating layer 30 include spin-on glass (SOG) and spin-on dielectrics (SOD). SOG and SOD are applied as a liquid, and the substrate 12 is spun to distribute the SOG or SOD. The SOG may include silicon-oxygen bonds, as well as silicon-hydrogen bonds. SOG is commercially available, such as ACCUGLASS® T-12B, available from HONEYWELL® Electronic Materials, 1349 Moffett Park Drive, Sunnyvale, Calif. 94089, USA. SOD may be liquid compounds including a silazane compound and optionally a solvent, where the SOD is applied to form a nitrogen and hydrogen containing insulating material. Some SODs include a catalyst to help convert the SOD to include silicon dioxide. SODs are commercially available, such as SPINFIL® 100, available from AZ Electronic Materials USA Corp, 70 Meister Ave., Branchburg, N.J. 08876, USA.

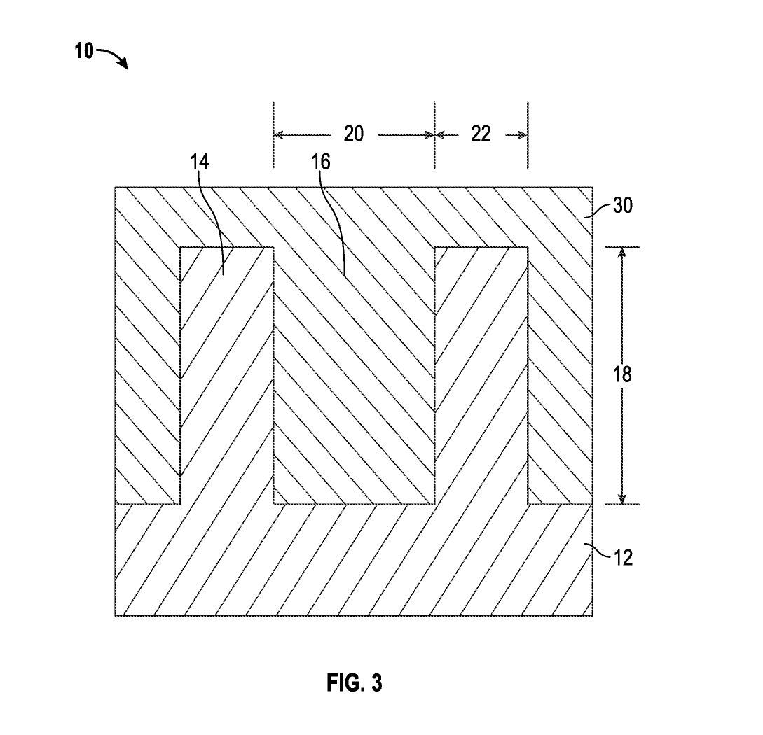

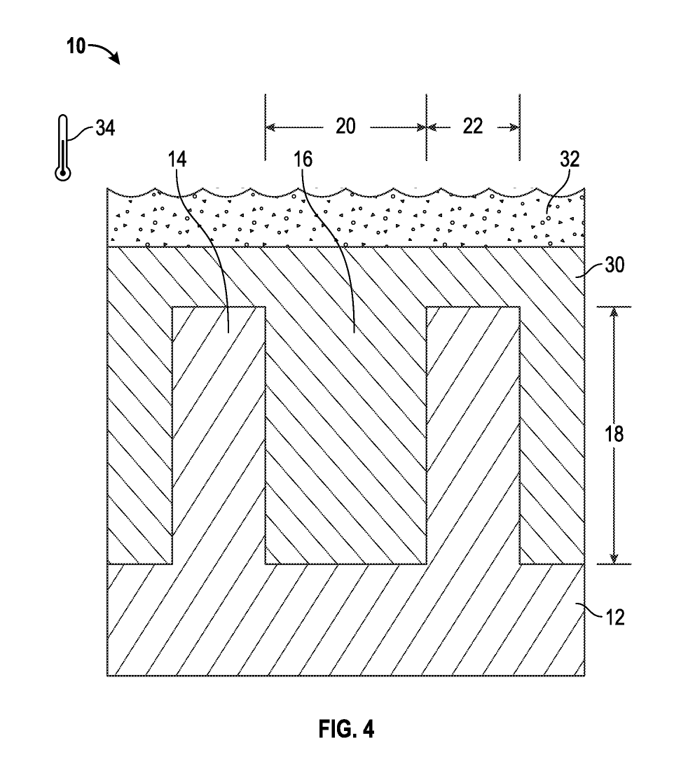

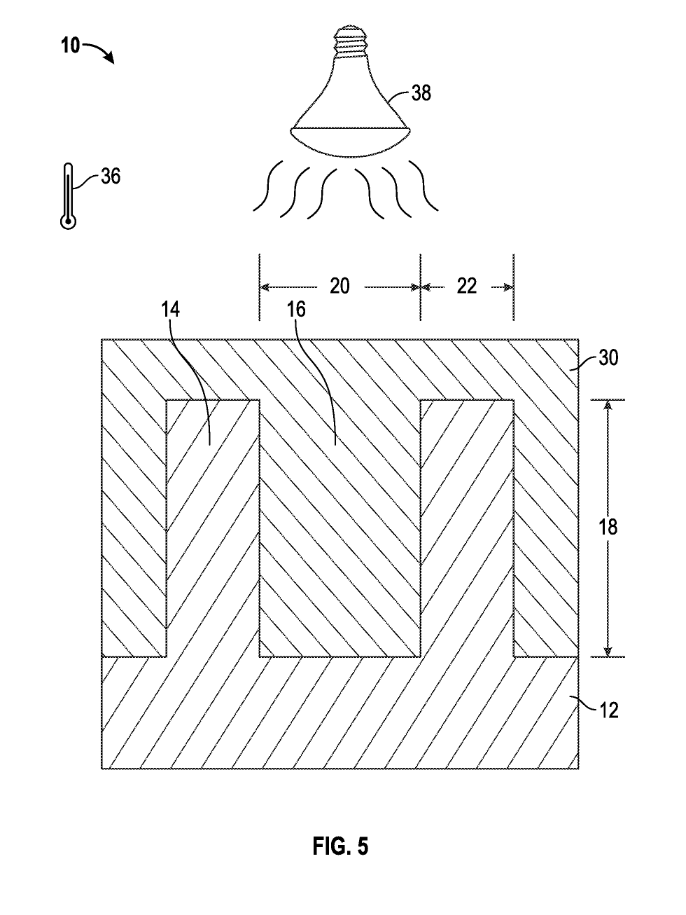

The insulating layer 30 is infused with water, as illustrated in an exemplary embodiment in FIG. 4. The insulating layer 30 may be infused with water by exposing the insulating layer 30 to liquid water 32, where deionized or distilled liquid water 32 may be used in some embodiments. After being exposed to liquid water 32, the insulating layer 30 is annealed in the presence of steam at a steam anneal temperature 34 of about 500° C. or less in some embodiments. In other embodiments, the steam anneal temperature 34 is about 400° C. or less, or about 300° C. or less yet other embodiments. Infusing the insulating layer 30 with water will convert silicon/nitrogen bonds to silicon/oxygen bonds in embodiments where the insulating layer 30 is a silicon and nitrogen containing film. The low temperature steam anneal (at a steam anneal temperature 34 of about 500° C. or less, 400° C. or less, or 300° C. or less) may produce a density of the insulating layer 30 of about 2.05 grams per cubic centimeter or less in some embodiments, or about 2.15 grams per cubic centimeter in other embodiments. The insulating layer 30 is primarily silicon dioxide after being infused with water. Low density silicon dioxide has a density of about 2.03 grams per cubic centimeter, medium density silicon dioxide has a density of about 2.13 grams per cubic centimeter, and high density silicon dioxide has a density of about 2.24 grams per cubic centimeter. In some embodiments, the steam anneal produces an insulating layer 30 with a low to medium density.

Referring to the exemplary embodiment illustrated in FIG. 5, the insulating layer 30 is densified with a dry anneal at a dry anneal temperature 36. The dry anneal may be performed in a nitrogen atmosphere that is essentially void of water, such as a water concentration of about 100 parts per million or less, so water remaining in the insulating layer 30 is removed during the dry anneal. Dry atmospheres other than nitrogen may be used in alternate embodiments, such as helium or other gases. The dry anneal temperature 36 varies for different embodiments, where the dry anneal temperature 36 is selected to be within the thermal budget for the substrate 12 or integrated circuit 10 at the time of the dry anneal. In different embodiments, the dry anneal temperature 36 may be about 800° C. or less, or about 600° C. or less, or about 500° C. or less, or about 400° C. or less. In many embodiments, the dry anneal temperature 36 is about the same or higher than the steam anneal temperature 34 discussed above. In an exemplary embodiment, the dry anneal increases the density of the insulating layer 30 by about 0.05 grams per cubic centimeter or more, or by about 0.07 grams per cubic centimeter or more in another embodiment, or by about 0.10 grams per cubic centimeter or more in yet another embodiment. The densifying process may produce a high density silicon dioxide in the insulating layer 30, so the insulating layer 30 has a density of about 2.18 grams per cubic centimeters or higher, or about 2.20 grams per cubic centimeter or higher, or about 2.24 grams per cubic centimeter or higher in various embodiments.

Higher dry anneal temperatures 36 tend to produce denser, higher quality silicon dioxide for the insulating layer 30, as discussed above. The insulating layer 30 may be irradiated during the dry anneal to add energy to the annealing process, and to aid in densifying the insulating layer 30 without exceeding the thermal budget. The dry anneal and irradiation of the insulating layer 30 may last from about 30 seconds to about 30 minutes in some embodiments, but different times can also be used. In an exemplary embodiment, a radiation source 38 may be used to expose the insulating layer 30 to irradiating energy during the dry anneal process. The radiation source 38 may be an ultra violet lamp in some embodiments, but the radiation source 38 may also be an infra-red lamp, a visible light lamp, a microwave source (if enough water is left in the insulating layer 30), or an electron beam source in various embodiments. The anneal time can be determined by the dry anneal temperature 36 and the intensity and type of the radiation source 38 used. In some embodiments, the upper surfaces of the insulating layer 30 may initially be densified at a faster rate than lower layers, because the upper surfaces receive more irradiating energy at first. However, the irradiating energy may pass through densified layers more easily than lower density layers, so the densification rate for lower layers may increase as the upper layers are densified. The densification process may include one or more dry anneals, and the same or different radiation sources, or no radiation source, can be used for different steps during the dry anneal.

The relatively low temperature of the dry anneal reduces the thermal cycle intensity over dry anneal processes with higher temperatures. The reduced thermal cycle intensity reduces stresses produced by different coefficients of expansion for the substrate 12 and the insulating layer 30, and this reduces stress on the walls of the trench 16. In embodiments where the trench 16 is formed between adjacent fins 14, the reduced stress reduces the likelihood of bending or breaking fins 14, such that the fins 14 are generally within about 2 degrees of vertical after the densification process. In embodiments where the trench 16 is formed in structures other than between adjacent fins 14, the reduced stress can help prevent damage or changes from differences in the coefficient of expansion between the walls of the trench 16 and the insulating layer 30.

The insulating layer 30 may be used to form a shallow trench isolation in some embodiments, as understood by those skilled in the art, but the insulating layer 30 may also be used as an insulating layer 30 between adjacent fins in finned field effect transistors FinFETS. The insulating layer 30 can also be used for other “gap fill” operations in the manufacture of an integrated circuit 10. Many additional processing steps may then be used to add components and develop the integrated circuit 10, as understood by those skilled in the art.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

1. A method of producing an integrated circuit comprising:
forming an insulating layer overlying a substrate, wherein the insulating layer is formed within a trench;
infusing the insulating layer with water; and
annealing the insulating layer at a dry anneal temperature while irradiating the insulating layer wherein the dry anneal temperature is about 800 degrees centigrade or less.

2. The method of claim 1 wherein forming the insulating layer comprises:
depositing a silicon and nitrogen containing film overlying the substrate by chemical vapor deposition.

3. The method of claim 1 wherein forming the insulating layer comprises forming the insulating layer overlying the substrate wherein the trench has an aspect ratio of about 5/1 or more, and wherein the insulating layer fills about 95 volume percent of the trench or more.

4. The method of claim 3 wherein annealing the insulating layer comprises densifying the insulating layer to a density of about 2.20 grams per cubic centimeter or greater, wherein the insulating layer comprises silicon dioxide after being annealed.

5. The method of claim 1 wherein infusing the insulating layer comprises:
exposing the insulating layer to water; and
annealing the insulating layer in the presence of steam at a steam anneal temperature of about 500 degrees centigrade or less.

6. The method of claim 1 wherein annealing the insulating layer comprises irradiating the insulating layer with ultraviolet light.

7. The method of claim 1 further comprising:
forming a plurality of fins in the substrate such that the trench is between adjacent fins, wherein the plurality of fins have a fin width of about 10 nm or less and wherein the plurality of fins are within 1 degree of vertical; and
wherein annealing the insulating layer comprises maintaining the plurality of fins within about 2 degrees of vertical.

8. The method of claim 1 wherein annealing the insulating layer comprises annealing the insulating layer wherein the dry anneal temperature is about 600 degrees centigrade or less.

9. The method of claim 1 wherein annealing the insulating layer comprises annealing the insulating layer wherein the dry anneal temperature is about 500 degrees centigrade or less.

10. The method of claim 1 wherein:
annealing the insulating layer comprises annealing the insulating layer wherein the dry anneal temperature is about 400 degrees centigrade or less; and
infusing the insulating layer with water comprises infusing the insulating layer with water at a steam anneal temperature of about 400 degrees centigrade or less.

11. A method of producing an integrated circuit comprising:
forming an insulating layer overlying a substrate, wherein the insulating layer is formed within a trench, and wherein the insulating layer comprises a silicon and nitrogen containing film;
converting the silicon and nitrogen containing film to silicon dioxide; and
densifying the insulating layer with a dry anneal of the insulating layer while irradiating the insulating layer with one or more of ultraviolet light, visible light, infrared light, or an electron beam, wherein densifying the insulating layer increases a density of the insulating layer by about 0.05 grams per cubic centimeter or more.

12. The method of claim 11 wherein densifying the insulating layer comprises irradiating the insulating layer with ultraviolet light.

13. The method of claim 12 wherein densifying the insulating layer comprises the dry anneal at a dry anneal temperature of about 800 degrees centigrade or less.

14. The method of claim 12 wherein densifying the insulating layer comprises the dry anneal at a dry anneal temperature of about 600 degrees centigrade or less.

15. The method of claim 12 wherein densifying the insulating layer comprises the dry anneal at a dry anneal temperature of about 400 degrees centigrade or less.

16. The method of claim 11 wherein converting the silicon and nitrogen containing film to the silicon dioxide comprises a steam anneal at a steam anneal temperature of about 500 degrees centigrade or less

17. A method of producing an integrated circuit comprising:
forming a plurality of fins in a substrate such that a trench is defined between adjacent fins, wherein the fins have a fin width of about 10 nanometers or less, wherein the fins are within about 1 degree of vertical, and wherein an aspect ratio of the trench is about a height of 10 or more to a width of 1;
forming an insulating layer within the trench, wherein the insulating layer fills about 95 volume percent of the trench or more; and
densifying the insulating layer such that the fins are within about 2 degrees of vertical, wherein densifying the insulating layer comprises a steam anneal followed by a dry anneal of the insulating layer at a dry anneal temperature of about 800 degrees centigrade or less; and
irradiating the insulating layer during the dry anneal with ultraviolet light, visible light, infrared light, an electron beam or a combination thereof.

18. The method of claim 17 wherein densifying the insulating layer comprises increasing a density of the insulating layer by about 0.05 grams per cubic centimeter or more.

19. The method of claim 17 wherein densifying the insulating layer comprises a dry anneal at a dry anneal temperature of about 600 degrees or less.

20. The method of claim 17 wherein densifying the insulating layer comprises creating a density of the insulating layer of about 2.20 grams per cubic centimeter or more.
